(19) United States
(12) Patent Application Publication
(10) Pub. No.: US 2015/0301568 A1
(43) Pub. Date: Oct. 22, 2015

(54) Thermal Solutions and Methods for Dissipating Heat from Electronic Devices Using the Same Side of an Anisotropic Heat Spreader

(71) Applicant: Laird Technologies, Inc., Earth City, MO (US)

(72) Inventors: Richard F. Hill, Parkman, OH (US); Jason L. Strader, Cleveland, OH (US)

(21) Appl. No.: 14/687,940

(22) Filed: Apr. 16, 2015

Related U.S. Application Data
(60) Provisional application No. 61/981,252, filed on Apr. 18, 2014.

(51) Int. Cl. G06F 1/20; H05K 7/20

(52) U.S. Cl. CPC G06F 1/206; H05K 7/20445

(57) ABSTRACT

Example embodiments of the present disclosure generally relate to thermal solutions and methods for dissipating or removing heat from electronic devices using the same side of an anisotropic heat spreader. In an example embodiment, a thermal solution generally includes a heat removal structure and an anisotropic heat spreader. The anisotropic heat spreader is configured such that the heat removal structure and the heat source are in thermal contact with a same side of the anisotropic heat spreader and such that a thermally-conductive heat path is provided along that same side of the anisotropic heat spreader from the heat source to the heat removal structure. Heat from the heat source may be transferrable to the same side of the anisotropic heat spreader from which heat is also transferrable to the heat removal structure.

### CROSS-REFERENCE TO RELATED APPLICATION

This application claims priority to U.S. Provisional Patent Application No. 61/981,252 filed Apr. 18, 2014. The entire disclosure of the aforementioned application is incorporated herein by reference in its entirety.

### FIELD

The present disclosure generally relates to thermal solutions and methods for dissipating or removing heat from electronic devices using the same side of an anisotropic heat spreader.

### BACKGROUND

This section provides background information related to the present disclosure which is not necessarily prior art.

Electrical components, such as semiconductors, transistors, etc., typically have pre-designed temperatures at which the electrical components optimally operate. Ideally, the pre-designed temperatures approximate the temperature of the surrounding air. But the operation of electrical components generates heat which, if not removed, can cause the electrical components to operate at temperatures significantly higher than normal or desirable operating temperatures. Such excessive temperatures may adversely affect the operating characteristics of the electrical component and the operation of any associated devices.

To avoid or at least reduce the adverse operating characteristics from the heat generation, the heat should be removed, for example, by conducting the heat from the operating electrical components to heat sinks. The heat sinks may then be cooled by conventional convection and/or radiation techniques. During conduction, the heat may pass from the operating electrical components to the heat sinks either by direct surface contact between the electrical components and heat sinks and/or by contact of the electrical components and heat sink surfaces through an intermediate medium or thermal interface material (TIM).

A thermal interface material may be used to fill the gap between thermal transfer surfaces, in order to increase thermal transfer efficiency as compared to having the gap filled with air, which is a relatively poor thermal conductor. In some devices, an electrical insulator may also be placed between the electrical component and the heat sink, in some cases this is the TIM itself.

### SUMMARY

This section provides a general summary of the disclosure, and is not a comprehensive disclosure of its full scope or all of its features.

Example embodiments of the present disclosure generally relate to thermal solutions and methods for dissipating or removing heat from electronic devices using the same side of an anisotropic heat spreader. In an example embodiment, a thermal solution generally includes a heat removal structure and an anisotropic heat spreader. The anisotropic heat spreader is configured such that the heat removal structure and the heat source are in thermal contact with a same side of the anisotropic heat spreader and such that a thermally-conductive heat path is provided along the same side of the anisotropic heat spreader from the heat source to the heat removal structure. Heat from the heat source may be transferrable to the same side of the anisotropic heat spreader from which heat is also transferrable to the heat removal structure.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a diagram showing a thermal solution for dissipating or removing heat from an electronic device according to an exemplary embodiment, in which a central processing unit (CPU) and a heat sink are on the same side of a graphite sheet, such that CPU heat may be supplied and transferred to the same side of the graphite heat spreader from which heat is also removed and transferred to the heat sink;

FIG. 2 is a diagram showing a thermal solution for dissipating or removing heat from an electronic device according to another exemplary embodiment, in which a CPU and a case of an electronic device are on the same side of a graphite sheet, such that CPU heat may be supplied and transferred to the same side of the graphite heat spreader from which heat is also removed and transferred to the case;

FIG. 3 is a diagram showing a conventional thermal solution in which a CPU and a heat sink are on opposite sides of a graphite sheet, such that CPU heat is supplied to and removed from opposite sides of the graphite sheet;

FIG. 4 is a diagram showing a conventional thermal solution in which a CPU and a case of an electronic device are on opposite sides of a graphite sheet, such that CPU heat is supplied to one side of the graphite sheet but heat is transferred to the case from the opposite side of the graphite sheet;

FIG. 5 is a diagram showing a thermal solution in which graphite is used to enhance a conventional foam gap filler to transfer heat from a heat source (e.g., CPU, etc.) to a heat removal structure (e.g., heat sink, case of an electronic device, etc.);

FIG. 6 shows the thermal solution of FIG. 5, where exemplary dimensions (in millimeters) are provided for purpose of illustration only;

FIG. 7 is a table of thermal resistances (R) in degrees Celsius per Watt (° C./W) calculated for different test samples having the configuration shown in FIG. 6, where the test samples respectively had 1, 10, and 40 graphite layers;

FIG. 8 is a table of thermal resistances (R) in degrees Celsius per Watt (° C./W) measured per ASTM D5470 for different test samples, where the data demonstrates the performance improvement that may be realized by exemplary embodiments of the present disclosure; and

FIG. 9 is a table of thermal resistance (R) in degrees Celsius per Watt (° C./W) and thermal conductivity (K) in Watts per meter Celsius (W/m·° C.) measured per ASTM D5470 for a thermal gap filler with and without synthetic graphite around the thermal gap filler, where the data demonstrates the performance improvement that may be realized by exemplary embodiments of the present disclosure.

### DETAILED DESCRIPTION

Example embodiments will now be described more fully with reference to the accompanying drawings.

Graphite is available in both natural form and synthetic form. The natural graphite is made from exfoliated natural graphite. The synthetic graphite is made by conversion of polymeric sheets to highly ordered graphite sheets. Both the natural and synthetic forms of graphite are used for heat spreading. The natural and synthetic forms of graphite are also highly anisotropic in thermal conductivity. The graphite sheet's highest thermal conductivity is in the direction of the plane (X-Y direction), while much lower conductivity is in the through thickness direction (Z-direction).

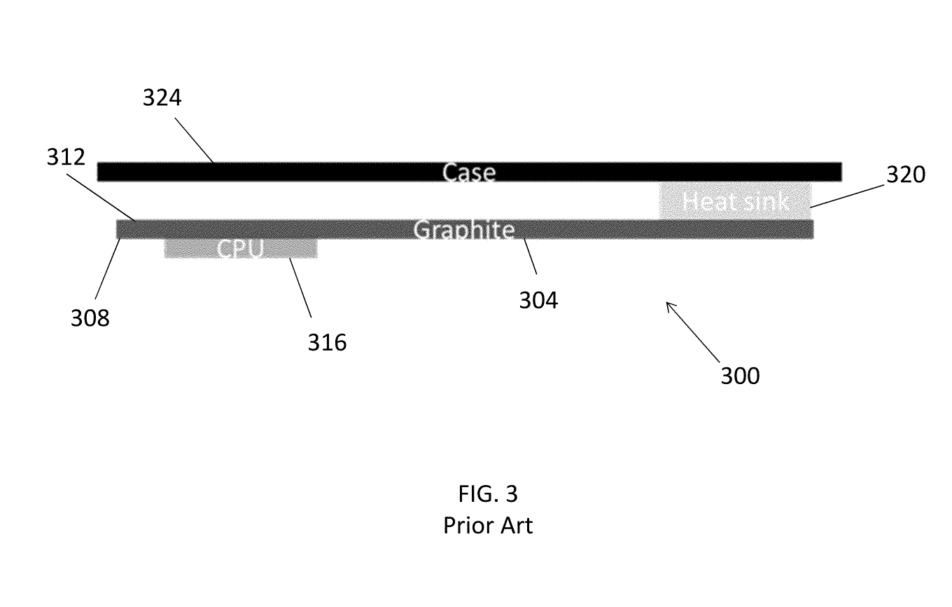

Conventionally, graphite has been used for heat spreading by placing one side of a graphite sheet against a heat source. The heat from the heat source is allowed to spread by making use of graphite's very high in plane thermal conductivity, but the heat is removed from the opposite side of the graphite sheet. For example, FIG. 3 shows a conventional thermal solution 300 in which a CPU 316 and a heat sink 320 are respectively on opposite first and second sides 308, 312 of a graphite sheet 304. During operation, heat from the CPU 316 is supplied and/or transferred to the first side 308 of the graphite sheet 304. The heat spreads laterally across or along the graphite sheet 304 because of the very high in plane thermal conductivity, which is in the X-Y horizontal direction or left-to-right direction in FIG. 3. The location of the heat sink 320 on the opposite side 312 of the graphite sheet 304 requires the heat to also pass through the graphite sheet's thickness in the through thickness direction, which is in the Z vertical direction or upwards in FIG. 3. In the through thickness direction, the graphite sheet 304 has a much lower thermal conductivity. Therefore, the overall thermal conductivity of the heat path from the CPU 316 through the graphite 304 to the case 324 is low as it includes the combination of heat spreading in the graphite's planar direction and passing through the graphite's thickness.

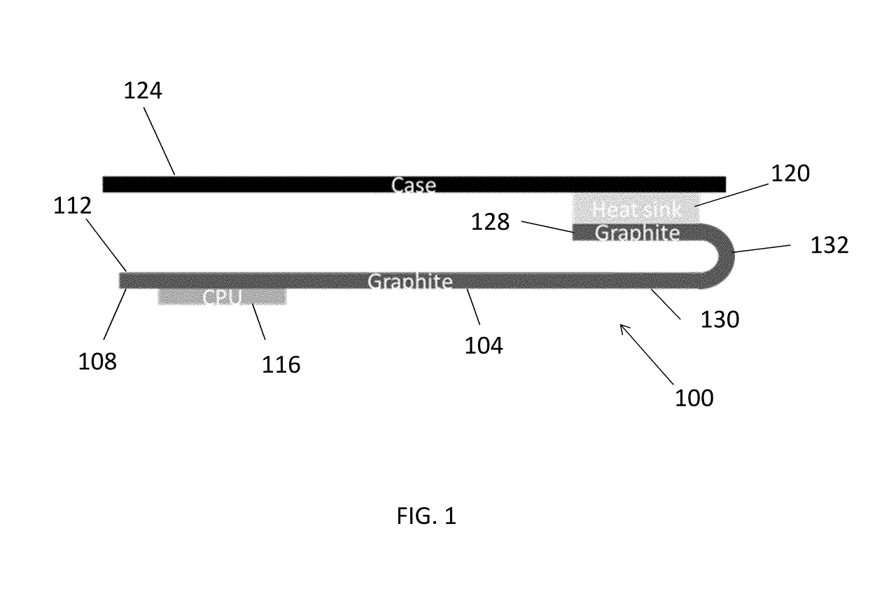

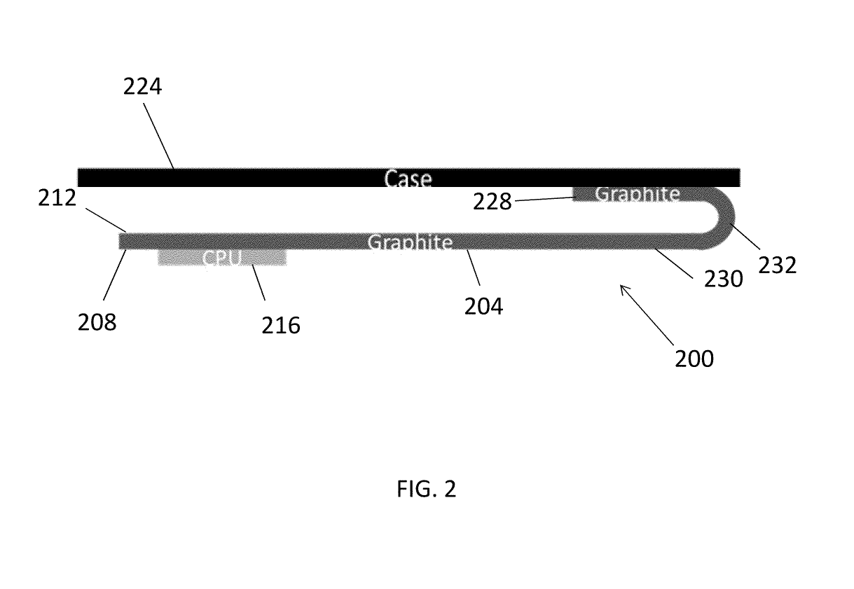

The inventors have recognized that by placing the heat source(s) and heat removal structure(s) on the same side of a graphite heat spreader, the effective thermal performance can be improved. Accordingly, the inventors developed and disclose herein exemplary embodiments of thermal solutions (e.g., FIG. 1, FIG. 2, etc.) and methods for dissipating or removing heat from electronic devices using the same side of an anisotropic heat spreader. In exemplary embodiments, a thermally-conducting heat path includes or is at least partially defined by or along the same side of an anisotropic heat spreader (e.g., graphite, filler oriented composites, stretched polymers, boron nitride, graphene, flexible or rigid graphite sheets, etc.). The inventors have found that using the same side of the anisotropic heat spreader improves or increases thermal performance of the thermal solutions as compared to thermal solutions (e.g., FIG. 3, etc.) that use opposite sides of an anisotropic heat spreader. The same side heat transfer thermal solutions disclosed herein may be superior and provide a more efficient way of cooling than conventional thermal solutions using opposite sides of a heat spreader.

Within electronic devices, there are typically limitations on the physical size and placement of thermal interface materials. For example, portable handheld electronic devices have a relatively small physical size that may make it unfeasible to accommodate the positioning of a flat graphite sheet so that heat is added to and removed from the same flat, planar side of the flat graphite sheet. After recognizing this obstacle, the inventors developed and disclose herein exemplary embodiments in which at least a portion of a graphite sheet is three-dimensionally configured or formed (e.g., twisted, bent, wrapped, folded, flexed, three-dimensionally reconfigured, etc.) to allow the same side of the graphite to be placed against and in thermal contact with a heat source(s) and a heat removal structure(s) even within relatively small devices in which the heat sources and the heat removal structures are spaced apart, not in the same plane, and at different heights relative to the graphite heat spreader.

For example, a heat removal structure and heat source may be respectively positioned above and below a graphite heat spreader (e.g., FIG. 1, FIG. 2, etc.). The graphite heat spreader may be interposed between the heat removal structure and heat source such that the heat removal structure and heat source are respectively above and below (in opposite directions relative to) the graphite heat spreader. In this example, the graphite heat spreader is configured to allow the heat source and heat removal structure to be placed against the same side or surface of the graphite heat spreader despite the heat removal structure and heat source being located in different upper and lower planes and/or in opposite upper and lower directions relative to the graphite heat spreader. The heat removal structure and heat source may be positioned against respective portions of the same side of the graphite heat spreader, which portions face in different directions (e.g., oppositely facing portions, upper and lower facing portions, etc.).

As another example, a heat source and heat removal structure may be respectively positioned above and below a graphite heat spreader. The graphite heat spreader may be interposed between the heat source and the heat removal structure such that the heat source and heat removal structure are respectively above and below (in opposite directions relative to) the graphite heat spreader. In this example, the graphite heat spreader is configured to allow the heat source and heat removal structure to be placed against the same side or surface of the graphite heat spreader despite the heat removal structure and heat source being located in different lower and upper planes and/or in opposite lower and upper directions relative to the graphite heat spreader. The heat removal structure and heat source may be positioned against respective portions of the same side of the graphite heat spreader, which portions face in different directions (e.g., oppositely facing portions, lower and upper facing portions, etc.).

For example, at least a portion of a flexible graphite sheet may be reconfigured or formed from its sheet-like planar construction into a three-dimensional extension or non-planar portion. The other portion of the flexible graphite sheet may retain its original sheet-like planar construction, which is out of plane or not coplanar with the three dimensional extension. As another example, an end portion of the flexible graphite sheet may be twisted, bent, wrapped, folded, or otherwise configured such that the end portion overlaps or overlays the flexible graphite sheet. The end portion may be folded or bent back (e.g., 180 degrees, etc.) such that there is a rounded, U-shaped, C-shaped, angled, folded, curved, or bent portion (e.g., portion 132 in FIG. 1, portion 232 in FIG. 2, etc.) between and connecting the end portion and the flexible graphite sheet. As a further example, both end portions of a flexible graphite sheet may be folded or bent such that there are two rounded, U-shaped, C-shaped, angled, folded, curved, or bent portions—one on each side of the graphite sheet. Yet another example includes graphite that is molded or otherwise formed into a continuous ring or annular shape, which, in turn, may be flexible or rigid.

As another example, a graphite heat spreader may be wrapped around a battery and then placed with the same side of the graphite to which heat is supplied against a heat removal structure(s), e.g., heat sink, an exterior case of a cellular phone, smart phone, etc. Thus, heat may be removed from a component behind a battery inside the device using the same side of the graphite, which is more effective than the conventional alternative of using opposite sides of the graphite.

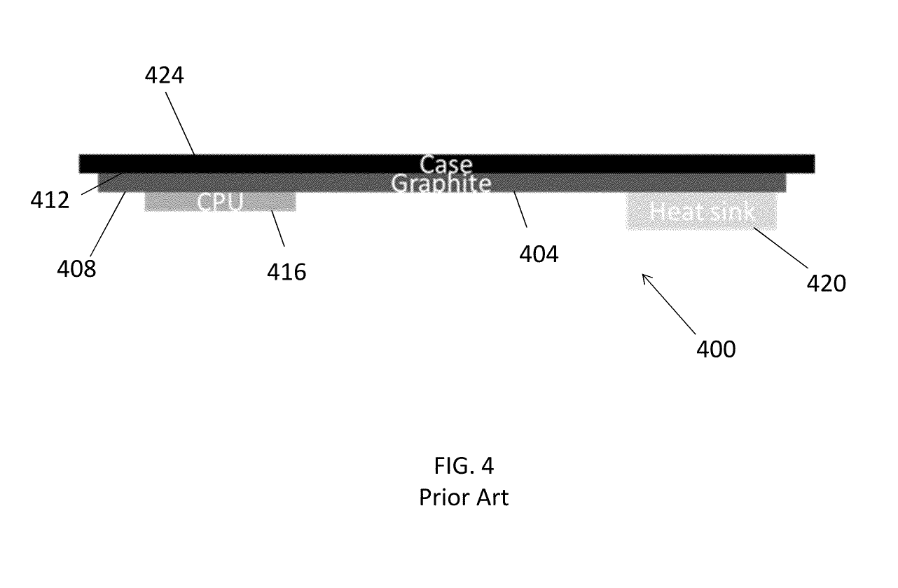

In exemplary embodiments, the same side of an anisotropic heat spreader is in thermal contact with (e.g., against, on, etc.) a heat source(s) and a heat removal structure(s) (e.g., a heat sink, a heat pipe, a heat plate, an exterior case or housing of a device, an interior wall within a device, combinations thereof, etc.). The same side of the anisotropic heat spreader establishes a thermally-conductive heat path, thermal joint, interface, or pathway along which heat may be transferred (e.g., conducted) from the heat source to the heat removal structure. Accordingly, heat from the heat source may be supplied to the same side of the anisotropic heat spreader from which heat is also removed or transferred to the heat removal structure. Using the same side of the anisotropic heat spreader provides more effective heat spreading and improves thermal performance than if using opposite sides of an anisotropic heat spreader. Stated differently, the inventors recognized that the same side heat transfer is superior to the opposite side heat transfer. For example, exemplary embodiments disclosed herein include a heat sink (e.g., heat sink 120 in FIG. 1, etc.) adjacent, directly against, and/or mounted to a case (e.g., case 124 in FIG. 1, etc.) of the device, which provides a better heat path that is superior in heat transfer as compared to the thermal solution shown in FIG. 4 in which the CPU 416 and heat sink 420 are on an opposite side of the graphite sheet 404 than the case 424.

By way of example, the anisotropic heat spreader may be attached to a heat source and a heat removal structure using an adhesive (e.g., a thermally-conductive adhesive about 5 microns thick, etc.) that is coated on or applied to one or both sides of the anisotropic heat spreader. In an exemplary embodiment in which the anisotropic heat spreader comprises graphite, the graphite may be enveloped in a film (e.g., a thermally-conductive plastic film about 5 microns thick, etc.) so that the graphite does not flake.

Installation of the anisotropic heat spreader may be dependent upon each application. Generally, however, the anisotropic heat spreader may be installed to one component either by hand or automated using an adhesive. This component would then be assembled as part of a device, and the anisotropic heat spreader would then be wrapped around other components during assembly. Adhesive or compressive forces may be used to hold the wrapped portion of the anisotropic heat spreader in place.

FIG. 1 illustrates an exemplary embodiment of a thermal solution or assembly 100 embodying one or more aspects of the present disclosure. As shown, the thermal solution 100 comprises an anisotropic heat spreader 104 having a first side or surface 108 and a second side or surface 112 opposite the first side 108.

In this exemplary embodiment, the anisotropic heat spreader 104 comprises a flexible graphite sheet. The flexible graphite sheet may comprise exfoliated graphite, compressed particles of exfoliated graphite, intercalating and exfoliating graphite flakes, combinations thereof, etc. For example, the anisotropic heat spreader may comprise intercalating and exfoliating graphite processed to form a flexible graphite sheet, which may include an adhesive layer thereon. By way of further example, the anisotropic heat spreader may be disposed within or sandwiched between layers of a thermoplastic, adhesive, thermal interface material, etc. These materials may be applied to (e.g., coated onto, etc.) the heat spreader on or along one or both sides.

The heat spreader 104 is configured, placed, and/or installed with its first side 108 against and in thermal contact with a central processing unit (CPU) 116 and a heat sink 120. Accordingly, this exemplary embodiment has the same side 108 of the heat spreader 104 against and in thermal contact with the CPU 116 and heat sink 120. Thus, heat from the CPU 116 may be supplied and transferred to the side 108 of the heat spreader 104, and heat may be removed and transferred from that same side 108 of the heat spreader 104 to the heat sink 120.

The heat sink 120 is against and in thermal contact with a portion of a case or housing 124 (e.g., an exterior case, an interior compartment, etc.) of an electronic device. The heat sink 120 and case 124 may collectively be referred to herein as a heat removal structure or assembly. In this example, a thermally-conductive heat path is thus defined from the CPU 116 along the side 108 of the heat spreader 104, through the heat sink 120, and to the case 124.

With continued reference to FIG. 1, a first portion 128 (e.g., end portion, etc.) of the heat spreader 104 is reconfigured or formed from its sheet-like planar construction into a three-dimensional extension or portion. A second portion 130 of the heat spreader 104 has or retains a sheet-like planar construction, which is out of plane or not coplanar with the three dimensional extension. In this particular example, the heat spreader's first portion 128 is twisted, wrapped, or otherwise configured such that the first portion 128 overlaps or overlays the second portion 130 of the heat spreader 104. The first portion 128 is folded or bent back (e.g., 180 degrees, etc.) over or along the second portion 130 such that there is a rounded, U-shaped, folded, or bent portion 132 which is between and connects the first and second portions 128, 130 of the heat spreader 104. The heat sink 120 and CPU 116 are positioned against oppositely facing surfaces of the first and second portions 128, 130 on the same side 108 of the heat spreader 104, which surfaces face in opposite lower and upper directions.

The thermally-conductive heat path from the CPU 116 to the case 124 shown in FIG. 1 is longer than the heat path shown in FIG. 3 in which the CPU 316 and heat sink 320 are on opposite sides 308, 312, such that heat must be transferred in plane and through the thickness of the graphite sheet 304. Even though the thermal solution 100 has a longer heat path than the thermal solution 300 shown in FIG. 3, the thermal performance of the thermal solution 100 may be better than the thermal performance of the thermal solution 300. The thermal solution 100 may provide a more efficient way of cooling and faster heat transfer by using the same side 108 of the graphite sheet 104 as compared to the thermal solution 300 that uses opposite sides 308, 312 of the graphite sheet 304. According to conventional wisdom, increasing the length of a heat path reduces thermal performance. But the inventors have recognized the counterintuitive way by which thermal performance may be improved by using the same side of a heat spreader to make optimal or better use of the anisotropic nature of the heat spreader even though the resulting thermally-conductive heat path may be longer.

In the illustrated example of FIG. 1, the heat spreader's first side 108 is directly against and in direct physical contact with the CPU 116 and the heat sink 120, while the heat sink 120 is directly against and in direct physical contact with the case 124. In other exemplary embodiments, one or more intervening components (e.g., thermal interface material and/or electromagnetic interference (EMI) shield, etc.) may be disposed between a heat source and a heat spreader, between a heat removal structure and the heat spreader, and/or between a heat sink and a portion of a case, housing, wall of an interior compartment, etc. For example, a thermally-conductive gap pad, phase change material, or other thermal interface material (referred to as TIM1) may be disposed between the same side of a heat spreader and a heat source; and/or a thermally-conductive gap pad, phase change material, or other thermal interface material (referred to as TIM2) may be disposed between the same side of the heat spreader and a heat sink. Or, for example, a second heat spreader may be between the heat sink and the case of the electronic device. The second heat spreader may help spread heat across the case, which, in turn, may help avoid hot spots on the case. As a further example, an air gap or thermal insulator may be between the heat sink and the case of the electronic device to help avoid hot spots on the case.

Exemplary embodiments of the present disclosure may include one or more of the heat spreaders, TIMs, and/or EMI shields disclosed in U.S. Patent Application Publication 2013/0265722, the entire disclosure of which is incorporated herein by reference.

FIG. 2 illustrates another exemplary embodiment of a thermal solution or assembly 200 embodying one or more aspects of the present disclosure. In this example, the thermal solution 200 comprises an anisotropic heat spreader 204 (e.g., graphite, etc.) having a first side or surface 208 and a second side or surface 212 opposite the first side 208.

The heat spreader 204 is configured, placed, and/or installed with its first side 208 against and in thermal contact with a central processing unit (CPU) 216 and a portion of a heat removal structure, which may be an exterior case or housing, a wall of an interior compartment, etc. of an electronic device. In this example, the heat removal structure is an exterior case or housing of an electronic device as there is no heat sink between case 224 and first side 208 of the heat spreader 204.

The same side 208 of the heat spreader 204 is directly against and in direct physical contact with the CPU 216 and case 224 without any intervening components therebetween. Thus, heat from the CPU 216 may be supplied and transferred to the first side 208 of the heat spreader 204, and heat may be removed and transferred from that same side 208 of the heat spreader 204 to the case 224. A thermally-conductive heat path is thus defined from the CPU 216 along the side 208 of the heat spreader 204 to the case 224.

With continued reference to FIG. 2, a first portion 228 (e.g., end portion, etc.) of the heat spreader 204 is reconfigured or formed from its sheet-like planar construction into a three-dimensional extension or non-planar portion. A second portion 230 of the heat spreader 204 has or retains a sheet-like planar construction, which is out of plane or not coplanar with the three dimensional extension. In this particular example, the heat spreader's first portion 228 is twisted, wrapped, or otherwise configured such that the first portion 228 overlaps or overlays the second portion 230. The first portion 228 is folded or bent back (e.g., 180 degrees, etc.) along or over the second portion 230 such that there is a rounded, U-shaped, folded, or bent portion 232, which is between and connects the first and second portions 228, 230 of the heat spreader 204. The case 224 and CPU 216 are positioned against oppositely facing surfaces of the first and second portions 228, 230 on the same side 208 of the heat spreader 204, which surfaces face in opposite lower and upper directions.

In the illustrated example of FIG. 2, the heat spreader's first side 208 is directly against and in direct physical contact with the CPU 216 and the case 224 without any intervening components therebetween. In other exemplary embodiments, one or more intervening components (e.g., a TIM and/or EMI shield, etc.) may be disposed between a heat source and a heat spreader and/or between a heat removal structure and the heat spreader. For example, a thermally-conductive gap pad, phase change material, or other TIM may be disposed between the same side of a heat spreader and a heat source and/or between the same side of the heat spreader and a device's exterior case or housing, a wall of an interior compartment, or other heat removal structure.

FIG. 3 shows a conventional thermal solution 300 in which a CPU 316 and a heat sink 320 are respectively on opposite first and second sides 308, 312 of a graphite sheet 304. During operation, heat from the CPU 316 is supplied and/or transferred to the first side 308 of the graphite sheet 304. The heat spreads laterally across or along the graphite sheet 304 because of the very high in plane thermal conductivity, which is in the X-Y horizontal direction or left-to-right direction in FIG. 3. The location of the heat sink 320 on the opposite side 312 of the graphite sheet 304 requires heat to also pass through the graphite sheet's thickness in the through thickness direction, which is in the Z vertical direction or upwards in FIG. 3. In the through thickness direction, the graphite sheet 304 has a much lower effective thermal conductivity. Therefore, the overall effective thermal conductivity of the heat path from the CPU 316 to the case 324 is low as it includes the combination of heat spreading in the graphite's planar direction and passing through the graphite's thickness.

FIG. 4 shows a conventional thermal solution 400 in which a CPU 416 and a case 424 of an electronic device are on opposite sides 408, 412, respectively, of a graphite sheet 404. In this thermal solution 400, heat from the CPU 416 is supplied to one side 408 of the graphite sheet 404. But heat is transferred to the case 424 from the opposite side 412 of the graphite sheet 404.

FIG. 4 also illustrates a heat sink 420 on the same side of the graphite sheet 404 as the CPU 416. But the heat sink 420 and the case 424 are on opposite sides 408, 412 of the graphite sheet 404. In this thermal solution 400, the graphite sheet 404 (due to its anisotropic nature) operates as a barrier for preventing immediate heat transfer from the CPU 416 to the case 424 in order to prevent hot spots forming on the case 424, which can be uncomfortable to the user.

Because the case 424 is on the opposite side 412 of the graphite sheet 404, the heat is required to pass through the graphite sheet's thickness in the through thickness direction, which is in the Z vertical direction or upwards in FIG. 4. In the through thickness direction, the graphite sheet 404 has a much lower effective thermal conductivity. Therefore, the overall effective thermal conductivity of the heat path from the CPU 416 to the case 424 is low as it includes the combination of spreading in the graphite's planar direction and passing through the graphite's thickness.

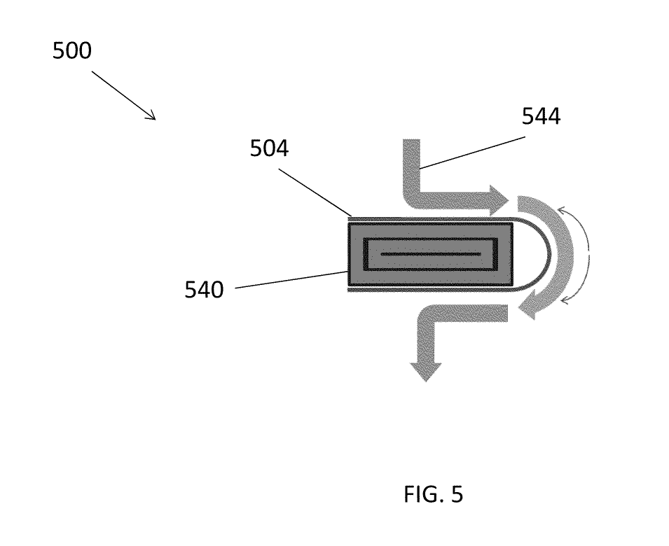

FIG. 5 illustrates another exemplary embodiment of a thermal solution or assembly 500 embodying one or more aspects of the present disclosure. In this example, the thermal solution 500 comprises an anisotropic heat spreader 504 (e.g., synthetic graphite, etc.) that is used to enhance a conventional foam gap filler 540 to transfer heat from a heat source (e.g., CPU, etc.) to a heat removal structure (e.g., heat sink, case of an electronic device, etc.). The heat flow is represented by the arrows 544.

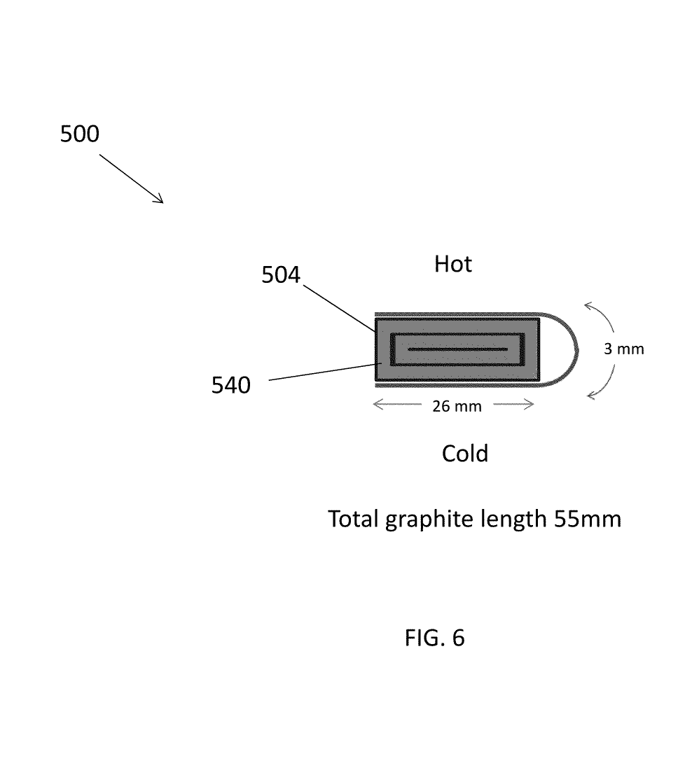

FIG. 6 shows the thermal solution 500 of FIG. 5, where exemplary dimensions (in millimeters) are provided for purpose of illustration only. Other exemplary embodiments may be configured differently, e.g., larger smaller, in a different shape, etc.

As shown in FIG. 6, the total graphite length is 55 millimeters. The distance from the midpoint to midpoint along the top and bottom (or hot and cold) surfaces is 26 millimeters. The curved portion of the graphite spanning the gap between the top and bottom surfaces is 3 millimeters.

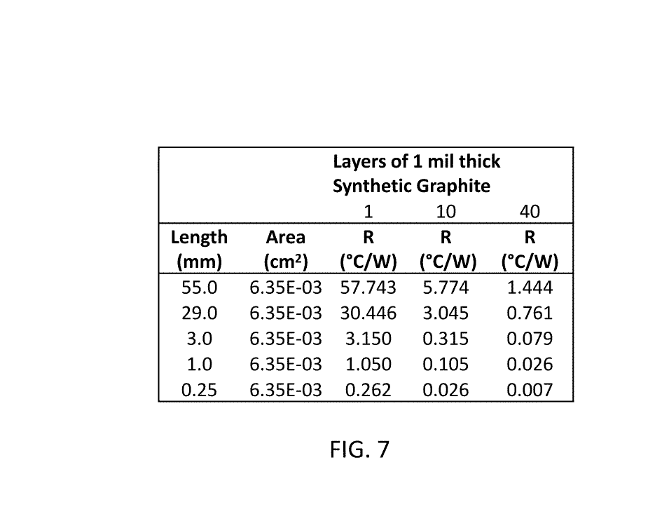

FIG. 7 is a table of thermal resistances (R) in degrees Celsius per Watt (° C./W) calculated for different test samples having the configuration shown in FIG. 6. The test samples respectively had 1, 10, and 40 graphite layers, and the length (in millimeters) and area (in square centimeters) as shown in the table. The test specimens included synthetic graphite material having a thickness of 25 microns, with a 5 micron adhesive layer on one side and polyethylene terephthalate (PET) cover films on both sides. The reported thermal conductivity was 1500 W/mK in the XY direction and 15 W/mK in the Z direction.

Utilizing a variation of Fourier's heat conduction equation, the thermal resistance R was defined as:

$$R = \frac{L}{A * K}$$

where L is the thickness (or gap in this case), A is the cross-sectional area perpendicular to heat flow (across the gap), and κ is the thermal conductivity of the material transferring the heat.

The combination of a long length (L) and a small cross sectional area (A) results in large thermal resistances. Small thermal resistances were not observed until the length was less than three millimeters and the number of graphite layers was greater than 10.

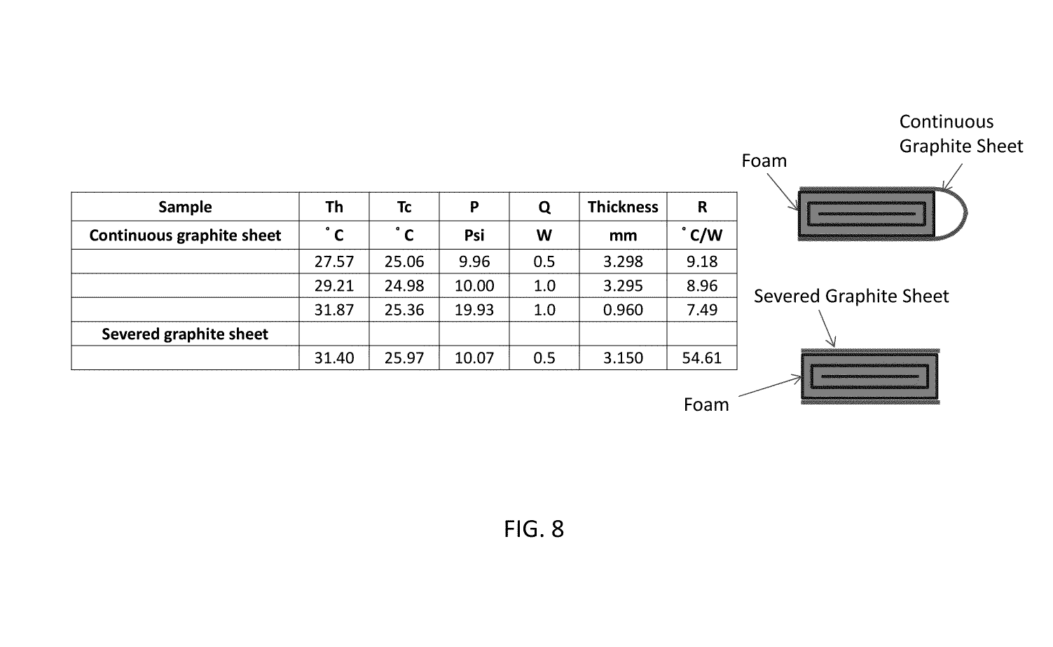

FIG. 8 is a table of thermal resistances (R) in degrees Celsius per Watt (° C./W) measured per ASTM D5470 for different test samples. This table also provides temperatures of the hot side (Th) and cold side (Tc) in degrees Celsius (° C.), pressure (P) in pounds per square inch (Psi), heat (Q) in Watts (W), and thickness in millimeters (mm). A comparison of the data for the samples having the continuous graphite sheets with the data for the samples with the severed graphite sheets demonstrates the performance improvement that may be realized by exemplary embodiments of the present disclosure.

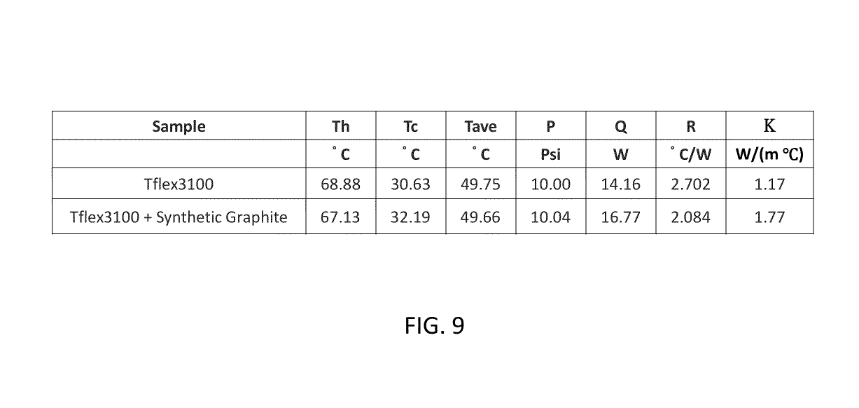

FIG. 9 is a table of thermal resistance (R) in degrees Celsius per Watt (° C./W) and thermal conductivity (K) in Watts per meter Celsius (W/m·° C.) measured per ASTM D5470 for a thermal gap filler with and without synthetic graphite around the thermal gap filler. For this particular testing, the test specimens included Laird Technologies Tflex™ 3100 ceramic filled silicone elastomer gap filler. As shown by FIG. 9, the test specimen (Tflex3100) that did not include the synthetic graphite had a thermal resistance of 2.702° C./W and a thermal conductivity (K) of 1.17 W/m·° C. By comparison, the test specimen (Tflex3100+synthetic graphite) that included synthetic graphite had a lower thermal resistance of 2.084° C./W and a higher thermal conductivity (K) of 1.77 W/m·° C. Accordingly, this particular testing shows that the incorporation of synthetic graphite around Tflex3100 resulted in a reduction of about 22.9% in thermal resistance and an increase in thermal conductivity of about 0.6 W/m·° C. Accordingly, this data in FIG. 9 demonstrates the performance improvement that may be realized by exemplary embodiments of the present disclosure.

In embodiments that include one or more thermal interface materials (e.g., TIM1, TIM2, etc.), a wide variety of materials may be used for any of the one or more TIMs in those embodiments. For example, the one or more TIMs may be formed from materials that are better thermal conductors and have higher thermal conductivities than air alone. The one or more TIMs may comprise thermal interface materials from Laird Technologies, such as any of the Tflex™ series gap fillers, Tpcm™ series thermal phase change materials, Tgrease™ series thermal greases, Tpli™ series gap fillers, Tgon™ series thermal interface materials, and/or IceKap™ series thermal interface materials. By way of further example, a TIM may be molded from thermally and electrically conductive elastomer. The TIMs may comprise thermally conductive compliant materials or thermally conductive interface materials formed from ceramic particles, metal particles, ferrite EMI/RFI absorbing particles, metal or fiberglass meshes in a base of rubber, gel, grease or wax, etc.

The tables below list example TIMs and properties. These example TIMs are commercially available from Laird Technologies, and, accordingly, have been identified by reference to trademarks of Laird Technologies. These tables are provided for purposes of illustration only and not for purposes of limitation.

| | | | | | Pressure of |
|---|---|---|---|---|---|
| | | | | | Thermal |
| | | | Thermal | Thermal | Impedance |
| | Construction | | Conductivity | Impedance | Measurement |
| Name | Composition | Type | [W/mK] | [° C.-cm²/W] | [kPa] |
| Tflex ™ 620 | Reinforced | Gap | 3.0 | 2.97 | 69 |
| | boron nitride | Filler | | | |
| | filled silicone | | | | |
| | elastomer | | | | |
| Tflex ™ 640 | Boron nitride | Gap | 3.0 | 4.0 | 69 |
| | filled silicone | Filler | | | |
| | elastomer | | | | |
| Tflex ™ 660 | Boron nitride | Gap | 3.0 | 8.80 | 69 |
| | filled silicone | Filler | | | |
| | elastomer | | | | |
| Tflex ™ 680 | Boron nitride | Gap | 3.0 | 7.04 | 69 |
| | filled silicone | Filler | | | |
| | elastomer | | | | |
| Tflex ™ 6100 | Boron nitride | Gap | 3.0 | 7.94 | 69 |
| | filled silicone | Filler | | | |
| | elastomer | | | | |
| Tpli ™ 210 | Boron nitride | Gap | 6 | 1.03 | 138 |
| | filled, silicone | Filler | | | |
| | elastomer, | | | | |
| | fiberglass | | | | |
| | reinforced | | | | |
| Tpcm ™ 583 | Non-reinforced | Phase | 3.8 | 0.12 | 69 |
| | film | Change | | | |
| Tflex ™ 320 | Ceramic filled | Gap | 1.2 | 8.42 | 69 |
| | silicone | Filler | | | |
| | elastomer | | | | |
| Tgrease ™ | Silicone-based | Thermal | 3.1 | 0.138 | 348 |
| 880 | based grease | Grease | | | |

The tables herein list various TIMs that have thermal conductivities of 1.2, 3, 3.1, 3.8, 4.7, 5.4, and 6 W/mK. These thermal conductivities are only examples as other embodiments may include a TIM with a thermal conductivity higher than 6 W/mK, less than 1.2 W/mK, or other values between 1.2 and 6 W/mk. For example, a TIM may be used that has a thermal conductivity higher than air's thermal conductivity of 0.024 W/mK, such as a thermal conductivity of about 0.3 W/mk, of about 3.0 W/mK, or somewhere between 0.3 W/mk and 3.0 W/mk, etc.

| | Tflex ™ | Tflex ™ | Tflex ™ | Tflex ™ | Tflex ™ | TEST |
|---|---|---|---|---|---|---|
| | 620 | 640 | 660 | 680 | 6100 | METHOD |
| Construction | Reinforced | Boron nitride | Boron nitride | Boron nitride | Boron | |
| & | boron nitride | filled silicone | filled silicone | filled silicone | nitride filled | |
| Composition | filled silicone | elastomer | elastomer | elastomer | silicone | |
| | elastomer | | | | elastomer | |
| Color | Blue-Violet | Blue-Violet | Blue-Violet | Blue-Violet | Blue-Violet | Visual |
| Thickness | 0.020″ | 0.040″ | 0.060″ | 0.080″ | 0.100″ | |
| | (0.51 mm) | (1.02 mm) | (1.52 mm) | (2.03 mm) | (2.54 mm) | |
| Thickness | ±0.003″ | ±0.004″ | ±0.006″ | ±0.008″ | ±0.010″ | |
| Tolerance | (±0.08 mm) | (±0.10 mm) | (±0.15 mm) | (±0.20 mm) | (±0.25 mm) | |
| Density | 1.38 g/cc | 1.34 g/cc | 1.34 g/cc | 1.34 g/cc | 1.34 g/cc | Helium |
| | | | | | | Pycnometer |
| Hardness | 40 shore 00 | 25 shore 00 | 25 shore 00 | 25 shore 00 | 25 shore 00 | ASTM |
| | | | | | | D2240 |
| Tensile | N/A | 15 psi | 15 psi | 15 psi | 15 psi | ASTM D412 |
| Strength | | | | | | |
| % Elongation | N/A | 75 | 75 | 75 | 75 | ASTM D412 |
| Outgassing | 0.13% | 0.13% | 0.13% | 0.13% | 0.13% | ASTM E595 |
| TML (Post | | | | | | |
| Cured) | | | | | | |
| Outgassing | 0.05% | 0.05% | 0.05% | 0.05% | 0.05% | ASTM E595 |
| CVCM (Post | | | | | | |
| Cured) | | | | | | |
| UL | UL 94 V0 | UL 94 V0 | UL 94 V0 | UL 94 V0 | UL 94 V0 | E180840 |
| Flammability | | | | | | |
| Rating | | | | | | |
| Temperature | −45° C. to | −45° C. to | −45° C. to | −45° C. to | −45° C. to | ASTMD |
| Range | 200° C. | 200° C. | 200° C. | 200° C. | 200° C. | 5470 |
| | | | | | | (modified) |
| Thermal | 3 W/mK | 3 W/mK | 3 W/mK | 3 W/mK | 3 W/mK | |
| Conductivity | | | | | | |
| Thermal | 0.46° C.-in²/W | 0.62° C.-in²/W | 0.85° C.-in²/W | 1.09° C.-in²/W | 1.23° C.-in²/W | ASTM |
| Impedance | 2.97° C.cm²/W | 4.00° C.cm²/W | 5.50° C.cm²/W | 7.04° C.cm²/W | 7.94° C.cm²/W | D5470 |
| @ 10 psi | | | | | | (modified) |
| @ 69KPa | | | | | | |
| Thermal | 600 ppm/° C. | 430 ppm/° C. | 430 ppm/° C. | 430 ppm° C. | 430 ppm/° C. | IPC-TM-650 |
| Expansion | | | | | | 2.4.24 |
| Breakdown | 3,000 | >5,000 | >5,000 | >5,000 | >5,000 | ASTM D149 |
| Voltage | Volts AC | Volts AC | Volts AC | Volts AC | Volts AC | |
| Volume | 2 × 10¹³ | 2 × 10¹³ | 2 × 10¹³ | 2 × 10¹³ | 2 × 10¹³ | ASTM D257 |
| Resistivity | ohm-cm | ohm-cm | ohm-cm | ohm-cm | ohm-cm | |
| Dielectric | 3.31 | 3.31 | 3.31 | 3.31 | 3.31 | ASTM D150 |
| Constant @ | | | | | | |
| 1MHz | | | | | | |

PROPERTIES

| | |
|---|---|
| Color | Grey |
| Density | 2.73 g/cc |
| Viscosity | <1,500,000cps |
| Brookfield Viscometer | TF-spindle at 2 rpm |
| | (helipath) and 23° C. |
| Temperature Range | −40-150° C. (−40-302° F.) |
| UL Flammability Rating | 94 VO File E-180840 |
| Thermal Conductivity | 3.1 W/mK |
| Thermal Resistance | |
| @ 10 psi | 0.014° C.-in²/W (0.090° C.-cm²/W) |
| @ 20 psi | 0.010° C.-in²/W (0.065° C.-cm²/W) |
| @ 50 psi | 0.009° C.-in²/W (0.058° C.-cm²/W) |
| Volume Resistivity (ASTM D257) | 9 × 10¹³ Ohm-cm |

| Typical Property | Description | Test Method |
|---|---|---|
| Color | Grey | Visual |
| Construction/Composition | Non-reinforced film | |
| Specific Gravity, g/cc | 2.51 | Helium Pycnometer |
| Minimum bond line thickness, | 0.025 (1) | Laird Test Method |
| mm (mils) | | |
| Thermal conductivity, W/mK | 4.7 | Hot Disk Thermal |
| | | Constants Analyzer |
| Thermal Resistance, | 0.064 (0.010) | ASTM D5470 |
| ° C.cm²/W (° C.in²/W) | | |
| Available Thickness, | 0.125-0.625 (5-25) | Laird Test Method |
| mm (mils) | | |
| Room Temperature | 85 | ASTM D2240 |
| Hardness, | | |
| shore 00 | | |
| Volume Resistivity, ohm-cm | 10¹⁵ | ASTM D257 |

SPECIFICATIONS

| PROPERTIES | Tpcm ™ 583 | Tpcm ™ 585 | Tpcm ™ 588 | Tpcm ™ 5810 |
|---|---|---|---|---|
| Construction & | Non-reinforced film | | | |
| composition | | | | |
| Color | Gray | | | |
| Thickness | 0.003″ (0.076 mm) | 0.005″ (0.127 mm) | 0.008″ (0.2 mm) | 0.010″ (0.25 mm) |
| Density | 2.87 g/cc | | | |
| Operating | −40° C. to 125° C. (−40° C. to 257° F.) | | | |
| temperature | | | | |
| range | | | | |
| Phase change | 50° C. (122° F.) | | | |
| softening | | | | |
| temperature | | | | |
| Thermal | | | | |
| resistance | | | | |
| 10 psi | 0.019° C.-in²/W | 0.020° C.-in²/W | 0.020° C.-in²/W | 0.020° C.-in²/W |
| | (0.12° C.-cm²/W) | (0.13° C.-cm²/W) | (0.13° C.-cm²/W) | (0.13° C.- |
| | | | | cm²/W) |
| 20 psi | 0.016° C.-in²/W | 0.016° C.-in²/W | 0.016° C.-in²/W | 0.016° C.-in²/W |
| | (0.10° C.-cm²/W) | (0.10° C.-cm²/W) | (0.10° C.-cm²/W) | (0.10° C.- |
| | | | | cm²/W) |
| 50 psi | 0.013° C.-in²/W | 0.013° C.-in²/W | 0.013° C.-in²/W | 0.013° C.-in²/W |
| | (0.08° C.-cm²/W) | (0.08° C.-cm²/W) | (0.08° C.-cm²/W) | (0.08° C.cm²/W) |

| | |
|---|---|
| Thermal | 3.8 W/mK |
| conductivity | |
| Volume | 3.0 × 10¹² ohm-cm |
| resistivity | |

| PROPERTIES | Tpcm ™ 780 | TEST METHOD |
|---|---|---|
| Color | Grey | Visual |
| Thickness, inches (mm) | 0.016″ (0.406) | |
| | 0.025″ (0.635) | |
| Thickness Tolerance, | ±0.0016″ (0.0406) | |
| inches (mm) | ±0.0025 (0.0635) | |
| Construction & Composition | Non-reinforced Film | |
| Specific Gravity, g/cc | 2.48 | Helium Pycnometer |
| Phase Change Softening | ~45° C. to 70° C. | |
| Range, ° C. | | |
| Thermal Conductivity, | 5.4 | Hot Disk Thermal |
| W/mK | | Constants Analyzer |
| Hardness (Shore 00) | 85 | ASTM D2240 |
| | 3 sec @ 21 C | |
| Thermal Resistance | 0.025 (0.004) | ASTM D5470 |
| 70° C., 345 kPa, ° C.-cm²/W | | (modified) |
| (50 psi, ° C.-in²/W) | | |
| Outgassing TML | 0.51% | ASTM E595 |
| Outgassing CVCM | 0.20% | ASTM E595 |

| | TPLI ™ | TPLI ™ | TPLI ™ | TPLI ™ | TPLI ™ | TEST |
|---|---|---|---|---|---|---|
| | 210 | 220 | 240 | 260 | 2100 | METHOD |
| Construction | Reinforced | Boron nitride | Boron nitride | Boron nitride | Boron nitride | |
| & | boron nitride | filled silicone | filled silicone | filled silicone | filled silicone | |
| Composition | filled silicone | elastomer | elastomer | elastomer | elastomer | |
| | elastomer | | | | | |
| Color | Rose | Blue | Yellow | Grey | Grey | Visual |
| Thickness | 0.010″ | 0.020″ | 0.040″ | 0.060″ | 0.100″ | |
| | (0.25 mm) | (0.51 mm) | (1.02 mm) | (1.52 mm) | (2.54 mm) | |
| Thickness | ±0.001″ | ±0.002″ | ±0.003″ | ±0.004″ | ±0.007″ | |
| Tolerance | (±0.025 mm) | (±0.05 mm) | (±0.08 mm) | (±0.10 mm) | (±0.18 mm) | |
| Density | 1.44 g/cc | 1.43 g/cc | 1.43 g/cc | 1.38 g/cc | 1.36 g/cc | Helium |
| | | | | | | Pycnometer |
| Hardness | 75 Shore 00 | 70 Shore 00 | 70 Shore 00 | 70 Shore 00 | 70 Shore 00 | ASTMD2240 |
| Tensile | N/A | 35 psi | 35 psi | 20 psi | 15 psi | ASTM D412 |
| Strength | | | | | | |
| % Elongation | N/A | 5 | 5 | 5 | 5 | ASTM D412 |
| Outgassing | 0.08% | 0.07% | 0.07% | 0.10% | 0.15% | ASTM E595 |
| TML (Post | | | | | | |
| Cured) | | | | | | |
| Outgassing | 0.03% | 0.02% | 0.02% | 0.04% | 0.07% | ASTM E595 |
| CVCM | | | | | | |
| (Post Cured) | | | | | | |
| UL | 94 HB | 94 HB | 94 HB | 94 HB | 94 HB | E180840 |
| Flammability | | | | | | |
| Rating | | | | | | |
| Temperature | −45° C. to | −45° C. to | −45° C. to | −45° C. to | −45° C. to | |
| Range | 200° C. | 200° C. | 200° C. | 200° C. | 200° C. | |
| Thermal | 6 W/mK | 6 W/mK | 6 W/mK | 6 W/mK | 6 W/mK | ASTM |
| Conductivity | | | | | | D5470 |
| | | | | | | (modified) |
| Thermal | 0.16° C.in²/W | 0.21° C.in²/W | 0.37° C.in²/W | 0.49° C.in²/W | 0.84° C.in²/W | ASTM |
| Impedance | 1.03° C.cm²/W | 1.35° C.cm²/W | 2.4° C.cm²/W | 3.35° C.cm²/W | 5.81° C.cm²/W | D5470 |
| @ 20 psi | | | | | | (modified) |
| @ 138KPa | | | | | | |
| Thermal | 51 ppm/C. | 123 ppm/C. | 72 ppm/C | 72 ppm/C. | 96 ppm/C. | IPC-TM-650 |
| Expansion | | | | | | 2.4.24 |
| Breakdown | 1,000 | 4,000 | >5,000 | >5,000 | >5,000 | ASTM D149 |
| Voltage | Volts AC | Volts AC | Volts AC | Volts AC | Volts AC | |
| Volume | 5 × 10¹³ | 5 × 10¹³ | 5 × 10¹³ | 5 × 10¹³ | 5 × 10¹³ | ASTM D257 |
| Resistivity | ohm-cm | ohm-cm | ohm-cm | ohm-cm | ohm-cm | |
| Dielectric | 3.21 | 3.21 | 3.26 | 3.26 | 3.4 | ASTM D150 |
| Constant @ | | | | | | |
| 1MHz | | | | | | |

TFLEX ™ 300 TYPICAL PROPERTIES

| | TFLEX ™ 300 | TEST METHOD |
|---|---|---|
| Construction | Filled silicone elastomer | NA |
| Color | Light green | Visual |
| Thermal Conductivity | 1.2 W/mK | ASTM D5470 |
| Hardness (Shore 00) | 27 (at 3 second delay) | ASTM D2240 |
| Density | 1.78 g/cc | Helium Pycnometer |
| Thickness Range | 0.020″-.200″ | |
| | (0.5-5.0 mm)* | |
| Thickness Tolerance | ±10% | |
| UL Flammability Rating | 94 V0 | UL |
| Temperature Range | −40° C. to 160° C. | NA |
| Volume Resistivity | 10\hat{ }13 ohm-cm | ASTEM D257 |
| Outgassing TML | 0.56% | ASTM E595 |
| Outgassing CVCM | 0.10% | ASTM E595 |
| Coefficient Thermal | 600 ppm/C | IPC-TM-650 |
| Expansion (CTE) | | 2.4.24 |

In addition to the examples listed in the tables above, other thermally-conductive compliant materials or thermally-conductive interface materials can also be used for a TIM. For example, a TIM may include compressed particles of exfoliated graphite, formed from intercalating and exfoliating graphite flakes, such as eGraf™ commercially available from Advanced Energy Technology Inc. of Lakewood, Ohio. Such intercalating and exfoliating graphite may be processed to form a flexible graphite sheet, which may include an adhesive layer thereon. A TIM may comprise one or more of the thermal interface materials (e.g., graphite, flexible graphite sheet, exfoliated graphite, etc.) disclosed in U.S. Pat. No. 6,482,520, U.S. Pat. No. 6,503,626, U.S. Pat. No. 6,841,250, U.S. Pat. No. 7,138,029, U.S. Pat. No. 7,150,914, U.S. Pat. No. 7,160,619, U.S. Pat. No. 7,267,273, U.S. Pat. No. 7,303,820, U.S. Patent Application Publication 2007/0042188, and/or U.S. Patent Application Publication 2007/0077434.

A TIM may comprise a pad of thermoplastic, and/or phase change material having a softening point (e.g., a melting temperature, phase change temperature, etc.) that is higher than, less than, or within a normal operating temperature range of a heat source (e.g., CPU having a normal operating temperature range from about 40° C. to 115° C., etc.). A TIM may comprise a thermal interface material including a thermally reversible gel as disclosed hereinafter and in U.S. Patent Application Publication No. US 2011/0204280, the entire disclosure of which is incorporated herein by reference in its entirety. A TIM may comprise a cross-linked material having joint-healing properties, a material that is not cross-linkable and has joint-healing properties, a viscous liquid having joint-healing properties, a cured material having joint-healing properties, etc.

A TIM may include compliant or conformable silicone pads, non-silicone based materials (e.g., non-silicone based gap filler materials, thermoplastic and/or thermoset polymeric, elastomeric materials, etc.), silk screened materials, polyurethane foams or gels, thermal putties, thermal greases, thermally-conductive additives, etc. A TIM may be configured to have sufficient conformability, compliability, and/or softness to allow the TIM material to closely conform to a mating surface when placed in contact with the mating surface, including a non-flat, curved, or uneven mating surface. A TIM may comprise an electrically conductive soft thermal interface material formed from elastomer and at least one thermally-conductive metal, boron nitride, and/or ceramic filler, such that the soft thermal interface material is conformable even without undergoing a phase change or reflow. A TIM may comprise a thermal interface phase change material, such as the Tpcm™ 583 listed in the above table.

A TIM may comprise one or more conformable thermal interface material gap filler pads having sufficient deformability, compliance, conformability, compressibility, and/or flexibility for allowing a pad to relatively closely conform to the size and outer shape of an electronic component when placed in contact with the electronic component when the shielding apparatus is installed to a printed circuit board over the electronic component. By engaging an electronic component in a relatively close fitting and encapsulating manner, a conformable thermal interface material gap pad may conduct heat away from the electronic component to the cover in dissipating thermal energy. Also, the thermal interface material gap filler pad may be a non-phase change material and/or be configured to deflect in order to adjust for tolerance or gaps. Such a thermal interface material gap filler pad would not be considered to be a spreadable paste.

Example embodiments of the present disclosure include thermal solutions suitable for use in dissipating or removing heat from electronic devices using the same side of an anisotropic heat spreader. In an example embodiment, a thermal solution generally includes a heat removal structure and an anisotropic heat spreader. The anisotropic heat spreader is configured such that the heat removal structure and the heat source are in thermal contact with a same side of the anisotropic heat spreader and such that a thermally-conductive heat path is provided along the same side of the anisotropic heat spreader from the heat source to the heat removal structure. Heat from the heat source is transferrable to the same side of the anisotropic heat spreader from which heat is also transferrable to the heat removal structure.

The anisotropic heat spreader may include a first portion and a second portion. The second portion may be out of plane with and/or overlap the first portion. The heat removal structure and the heat source may be respectively positioned along the first and second portions on the same side of the anisotropic heat spreader. The first portion may be bent back along the second portion such that the first portion overlaps the second portion and a bent portion connects the first and second portions. The first and second portions may have oppositely facing surfaces on the same side of the anisotropic heat spreader. The heat removal structure and the heat source may be positioned along the oppositely facing surfaces of the first and second portions, respectively, on the same side of the anisotropic heat spreader.

The anisotropic heat spreader may comprise one or more of graphite, a flexible or rigid graphite sheet, synthetic graphite, graphene, polymer (e.g., a polymer that is stretched to be anisotropic, etc.), compressed particles of exfoliated graphite formed from intercalating and exfoliating graphite flakes, intercalated and exfoliated graphite flakes formed into a flexible graphite sheet, filler oriented composites, boron nitride, graphene, molded graphite, etc.

The heat removal structure may comprise a heat sink and/or a case of an electronic device.

The heat removal structure may comprise a heat sink in thermal contact with a case of an electronic device and the same side of the anisotropic heat spreader. Heat from the heat source may be transferrable to the same side of the anisotropic heat spreader and along the thermally-conductive heat path. Heat may be transferrable from the same side of the anisotropic heat spreader through the heat sink to the case. A thermal interface material may be between the heat sink and the same side of the anisotropic heat spreader; and/or a thermal interface material may be between the heat sink and the case; and/or a thermal interface material may be between the heat source and the same side of the anisotropic heat spreader.

The heat removal structure may comprise a case of an electronic device. Heat from the heat source may be transferrable to the same side of the anisotropic heat spreader and along the thermally-conductive heat path. Heat may be transferrable from the same side of the anisotropic heat spreader to the case.

The heat removal structure may comprise a heat sink. The heat sink may be directly against the same side of the anisotropic heat spreader without any intervening components therebetween. Or, a thermal interface material may be between the heat sink and the same side of the anisotropic heat spreader.

The heat removal structure may comprise a case of an electronic device. A portion of the case may be directly against the same side of the anisotropic heat spreader without any intervening components therebetween. Or, a thermal interface material may be between a portion of the case and the same side of the anisotropic heat spreader.

Exemplary embodiments of the present disclosure also include electronic devices. In an exemplary embodiment, an electronic device generally includes a heat source, a heat removal structure, and an anisotropic heat spreader as disclosed herein. The anisotropic heat spreader is configured such that the heat removal structure and the heat source are in thermal contact with a same side of the anisotropic heat spreader and such that a thermally-conductive heat path is provided along the same side of the anisotropic heat spreader from the heat source to the heat removal structure. Heat from the heat source is transferrable to the same side of the anisotropic heat spreader from which heat is also transferrable to the heat removal structure.

Example embodiments of the present disclosure further include methods of establishing a thermally-conductive heat path within an electronic device from a heat source to a heat removal structure. In an exemplary embodiment, a method generally includes positioning an anisotropic heat spreader relative to the heat removal structure and the heat source such that the heat removal structure and the heat source are in thermal contact with a same side of the anisotropic heat spreader and such that the thermally-conductive heat path is provided along the same side of the anisotropic heat spreader from the heat source to the heat removal structure. Heat from the heat source is transferrable to the same side of the anisotropic heat spreader. Heat is transferrable from the same side of the anisotropic heat spreader to the heat removal structure.

The method may include configuring the anisotropic heat spreader to have a first portion out of plane with and/or overlapping a second portion. The first and second portions may have oppositely facing surfaces on the same side of the anisotropic heat spreader. The method may also include positioning the anisotropic heat spreader such that the heat removal structure and the heat source are along the oppositely facing surfaces of the first and second portions, respectively, on the same side of the anisotropic heat spreader.

Exemplary embodiments (e.g., 100, 200, 500, etc.) disclosed herein may be used with a wide range of electronic devices, electronic components, heat sources, and heat removal structures. Example heat sources or heat generating components include processors, computer chips, braking systems, heating elements, power converters, amplification chips, insulated-gate bipolar transistors (IGBT), graphics processing units (GPU), memory chips, semiconductors, transistors, any various other electronics system components, etc. Example heat removal structures include heat sinks, heat pipes, heat plates, exterior cases or housings of devices, interior walls within devices, thermal interface materials, EMI shields, combinations thereof, etc. By way of example only, exemplary applications include printed circuit boards, high frequency microprocessors, central processing units, graphics processing units, laptop computers, notebook computers, desktop personal computers, computer servers, thermal test stands, portable communications terminals, cellular phones, smart phones, tablets, etc. Accordingly, aspects of the present disclosure should not be limited to use with any one specific type of end use, electronic component, part, device, equipment, heat source, heat removal structure, etc.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. In addition, advantages and improvements that may be achieved with one or more exemplary embodiments of the present disclosure are provided for purpose of illustration only and do not limit the scope of the present disclosure, as exemplary embodiments disclosed herein may provide all or none of the above mentioned advantages and improvements and still fall within the scope of the present disclosure.

Specific dimensions, specific materials, and/or specific shapes disclosed herein are example in nature and do not limit the scope of the present disclosure. The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter (i.e., the disclosure of a first value and a second value for a given parameter can be interpreted as disclosing that any value between the first and second values could also be employed for the given parameter). For example, if Parameter X is exemplified herein to have value A and also exemplified to have value Z, it is envisioned that parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, and 3-9.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The term “about” when applied to values indicates that the calculation or the measurement allows some slight imprecision in the value (with some approach to exactness in the value; approximately or reasonably close to the value; nearly). If, for some reason, the imprecision provided by “about” is not otherwise understood in the art with this ordinary meaning, then “about” as used herein indicates at least variations that may arise from ordinary methods of measuring or using such parameters. For example, the terms “generally”, “about”, and “substantially” may be used herein to mean within manufacturing tolerances.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements, intended or stated uses, or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A thermal solution suitable for use in dissipating heat from a heat source within an electronic device, the thermal solution comprising:
a heat removal structure; and
an anisotropic heat spreader configured such that the heat removal structure and the heat source are in thermal contact with a same side of the anisotropic heat spreader and such that a thermally-conductive heat path is provided along the same side of the anisotropic heat spreader from the heat source to the heat removal structure;
whereby heat from the heat source is transferrable to the same side of the anisotropic heat spreader from which heat is also transferrable to the heat removal structure.

2. The thermal solution of claim 1, wherein:
the anisotropic heat spreader includes a first portion and a second portion out of plane with the first portion; and
the heat removal structure and the heat source are respectively positioned along the first and second portions on the same side of the anisotropic heat spreader.

3. The thermal solution of claim 1, wherein:
the anisotropic heat spreader includes a first portion and a second portion, the first and second portions having oppositely facing surfaces on the same side of the anisotropic heat spreader; and
the heat removal structure and the heat source are positioned along the oppositely facing surfaces of the first and second portions, respectively, on the same side of the anisotropic heat spreader.

4. The thermal solution of claim 1, wherein:
the anisotropic heat spreader includes a first portion and a second portion, the first portion overlapping the second portion; and
the heat removal structure and the heat source are respectively positioned along the first and second portions on the same side of the anisotropic heat spreader.

5. The thermal solution of claim 1, wherein:
the anisotropic heat spreader includes a first portion and a second portion, the first portion is bent back along the second portion such that a bent portion connects the first and second portions; and
the heat removal structure and the heat source are respectively positioned along the first and second portions on the same side of the anisotropic heat spreader.

6. The thermal solution of claim 1, wherein the anisotropic heat spreader comprises one or more of:
graphite;
a flexible graphite sheet;
synthetic graphite;
graphene;
polymer;
boron nitride;
compressed particles of exfoliated graphite formed from intercalating and exfoliating graphite flakes; and
intercalated and exfoliated graphite flakes formed into a flexible graphite sheet.

7. The thermal solution of claim 1, wherein the heat removal structure comprises a heat sink and/or a case of the electronic device.

8. The thermal solution of claim 1, wherein:
the heat removal structure comprises a heat sink in thermal contact with the same side of the anisotropic heat spreader;
heat from the heat source is transferrable to the same side of the anisotropic heat spreader and along the thermally-conductive heat path; and
heat is transferrable from the same side of the anisotropic heat spreader through the heat sink.

9. The thermal solution of claim 8, further comprising:
a thermal interface material between the heat sink and the same side of the anisotropic heat spreader; and/or
a thermal interface material between the heat source and the same side of the anisotropic heat spreader; and/or
a thermal interface material or a heat spreader between the heat sink and a case of the electronic device.

10. The thermal solution of claim 1, wherein
the heat removal structure comprises a case of the electronic device; and
heat from the heat source is transferrable to the same side of the anisotropic heat spreader and along the thermally-conductive heat path; and
heat is transferrable from the same side of the anisotropic heat spreader to the case.

11. The thermal solution of claim 1, wherein the heat removal structure comprises a heat sink, and wherein:
the heat sink is directly against the same side of the anisotropic heat spreader without any intervening components therebetween; and
a thermal interface material is between the heat sink and the same side of the anisotropic heat spreader.

12. The thermal solution of claim 1, wherein the heat removal structure comprises a case of the electronic device, and wherein:
a portion of the case is directly against the same side of the anisotropic heat spreader without any intervening components therebetween; or
a thermal interface material is between a portion of the case and the same side of the anisotropic heat spreader.

13. An electronic device comprising a heat source, a case, and the thermal solution of claim 1, wherein the heat removal structure comprises a heat sink in thermal contact with the case, and wherein the anisotropic heat spreader is positioned relative to the heat source and the heat sink such that:
heat from the heat source is transferrable to the same side of the anisotropic heat spreader; and
heat is transferrable from the same side of the anisotropic heat spreader through the heat sink to the case.

14. An electronic device comprising:
a heat source;
a heat removal structure; and
an anisotropic heat spreader configured such that the heat removal structure and the heat source are in thermal contact with a same side of the anisotropic heat spreader and such that a thermally-conductive heat path is provided along the same side of the anisotropic heat spreader from the heat source to the heat removal structure;
whereby heat from the heat source is transferrable to the same side of the anisotropic heat spreader from which heat is also transferrable to the heat removal structure.

15. The electronic device of claim 14, wherein:
the anisotropic heat spreader includes a first portion and a second portion out of plane with the first portion; and
the heat removal structure and the heat source are respectively positioned along the first and second portions on the same side of the anisotropic heat spreader.

16. The electronic device of claim 14, wherein:
the anisotropic heat spreader includes a first portion and a second portion, the first portion is bent back along the second portion such that the first portion overlaps the second portion and a bent portion connects the first and second portions, the first and second portions having oppositely facing surfaces on the same side of the anisotropic heat spreader; and
the heat removal structure and the heat source are positioned along the oppositely facing surfaces of the first and second portions, respectively, on the same side of the anisotropic heat spreader.

17. The electronic device of claim 14, wherein the anisotropic heat spreader comprises one or more of:
graphite;
a flexible graphite sheet;
synthetic graphite;
graphene;
polymer;
compressed particles of exfoliated graphite formed from intercalating and exfoliating graphite flakes; and
intercalated and exfoliated graphite flakes formed into a flexible graphite sheet.

18. The electronic device of claim 14, wherein:
the heat removal structure comprises a heat sink in thermal contact with the same side of the anisotropic heat spreader;
heat from the heat source is transferrable to the same side of the anisotropic heat spreader and along the thermally-conductive heat path; and
heat is transferrable from the same side of the anisotropic heat spreader to the heat sink.

19. A method of establishing a thermally-conductive heat path within an electronic device from a heat source to a heat removal structure, the method comprising positioning an anisotropic heat spreader relative to the heat removal structure and the heat source such that the heat removal structure and the heat source are in thermal contact with a same side of the anisotropic heat spreader and such that the thermally-conductive heat path is provided along the same side of the anisotropic heat spreader from the heat source to the heat removal structure, whereby heat from the heat source is transferrable to the same side of the anisotropic heat spreader from which heat is also transferrable to the heat removal structure.

20. The method of claim 19, wherein positioning the anisotropic heat spreader includes:
configuring the anisotropic heat spreader to have a first portion out of plane with and/or overlapping a second portion, the first and second portions having oppositely facing surfaces on the same side of the anisotropic heat spreader; and
positioning the anisotropic heat spreader such that the heat removal structure and the heat source are along the oppositely facing surfaces of the first and second portions, respectively, on the same side of the anisotropic heat spreader.
